(19) United States
(12) Patent Application Publication
(10) Pub. No.: US 2016/0285025 A1
(43) Pub. Date: Sep. 29, 2016

(54) TANDEM WHITE ORGANIC LIGHT-EMITTING DEVICE

(71) Applicant: CORNING PRECISION MATERIALS CO., LTD, Chungcheongnam-do (KR)

(72) Inventor: June Hyong Park, Chungcheongnam-do (KR)

(73) Assignee: Corning Precision Materials Co., Ltd., Chungcheongnam-do (KR)

(21) Appl. No.: 15/036,322

(22) PCT Filed: Nov. 12, 2014
(86) PCT No.: PCT/KR2014/010864

§ 371 Date: May 12, 2016

(30) Foreign Application Priority Data
Nov. 14, 2013 (KR) 10-2013-0138175

(51) Int. Cl. H01L 51/50; H01L 51/52

(52) U.S. Cl. CPC H01L 51/504; H01L 51/5278; H01L 2251/301; H01L 2251/303; H01L 2251/558

(57) ABSTRACT

The present invention relates to a tandem white organic light-emitting device and, more specifically, to a tandem white organic light-emitting device having excellent electrical properties due to the enhanced conductivity of charge generation layers formed between a plurality of organic light-emitting layers that are being laminated. To this end, the present invention provides a tandem white organic light-emitting device comprising: a base substrate; a first electrode formed on the base substrate; a second electrode formed opposite to the first electrode; two or more organic light-emitting layers formed between the first and second electrodes; and charge generation layers formed between the adjacent organic light-emitting layers, wherein the charge generation layers are formed from a laminated structure of a first metal layer and a second metal layer having different work functions.

### TECHNICAL FIELD

The present invention relates to a tandem white organic light-emitting device (OLED). More particularly, the present invention relates to a tandem white OLED having superior electrical properties due to enhanced conductivity of charge generation layers formed between a plurality of laminated organic light-emitting layers.

### BACKGROUND ART

Recently, display devices and lighting devices have been required to be, for example, lightweight, thin, highly efficient, and eco-friendly. In order to satisfy these requirements, studies into the use of organic light-emitting devices (OLEDs) have been actively undertaken.

OLEDs are divided into single OLEDs, each of which has a single organic light-emitting layer, and tandem OLEDs, each of which has two or more organic light-emitting layers that are stacked on each other in series. Tandem OLEDs may be used in display devices or lighting devices requiring a high level of luminance and a long lifespan due to higher reliability and longer lifespans thereof, as compared to single OLEDs.

A white OLED has different organic light-emitting layers between an anode and a cathode, in order to emit different colors of light. A charge generation layer is disposed between the organic light-emitting layers. To date, the charge generation layer has been formed of an organic material, a salt, an organic-inorganic material, or a metal-organic material. In this case, the thickness of the charge generation layer is inevitably increased, and the conductivity of the charge generation layer is reduced. This may make it difficult to form a high-quality charge generation layer, which is problematic. Consequently, the electrical properties of a white OLED may be reduced.

Related Art Document

Patent Document 1: Japanese Patent No. 4966176 (Apr. 6, 2012)

### DISCLOSURE

### Technical Problem

Various aspects of the present invention provide a tandem white organic light-emitting device (OLED) having superior electrical properties due to enhanced conductivity of charge generation layers formed between a plurality of laminated organic light-emitting layers.

### Technical Solution

According to an aspect, a tandem white organic light-emitting device (OLED) may include: a base substrate; a first electrode disposed on the base substrate; a second electrode facing the first electrode; two or more organic light-emitting layers disposed between the first electrode and the second electrode; and one or more charge generation layers respectively disposed between adjacent organic light-emitting layers among the two or more organic light-emitting layers. Each of the charge generation layers has a laminated structure including a first metal layer and a second metal layer having different work functions.

The work function of the first metal layer may be lower than the work function of the second metal layer.

The first metal layer may abut an electron layer of one organic light-emitting layer among the two or more organic light-emitting layers, and the second metal layer may abut a hole layer of an adjacent organic light-emitting layer among the two or more organic light-emitting layers.

The first metal layer may include one element or a combination of two or more elements selected from the group consisting of Li, Cs, Na, Ba, Ca, Mg, and Al.

The second metal layer may include one element or a combination of two or more elements selected from the group consisting of Au, Ag, Cu, Sn, Ti, and Al.

Each of the charge generation layers may further include an insulating layer situated between the first metal layer and the second metal layer.

The insulating layer may include a polymer insulating layer or may include one selected from the group consisting of SiOₓ, SiNₓ, WO_{K}, MoOₓ, and Al₂O₃.

Each of the charge generation layers may further include a semiconductor layer situated between the first metal layer and the second metal layer.

The semiconductor layer may include one selected from the group consisting of conjugated polymers, conjugated molecules, metal oxides, and silicon.

The thickness of each of the charge generation layers may range from 0.1 nm to 50 nm.

### Advantageous Effects

As set forth above, the charge generation layers (CGLs) are situated between the plurality of organic light-emitting layers to connect the same. Each of the charge generation layers is formed of a laminated structure of metals having different work functions, such as a structure of a first metal layer and a second metal layer, a structure of a first metal layer, a semiconductor layer, and a second metal layer, and a structure of a first metal layer, an insulating layer, and a second metal layer. This can consequently improve the conductivity of the charge generation layers, thereby allowing a tandem white OLED having superior electrical properties to be realized.

### DESCRIPTION OF DRAWINGS

FIG. 1 is a conceptual cross-sectional view schematically illustrating a tandem organic light-emitting device (OLED) according to an exemplary embodiment of the present invention.

### BEST MODE

Hereinafter, a tandem organic light-emitting device (OLED) according to an exemplary embodiment of the present invention will be described in detail with reference to the accompanying drawing.

In addition, in the description of the present invention, detailed descriptions of known functions and components will be omitted in the case that the subject matter of the present invention is rendered unclear by the inclusion thereof.

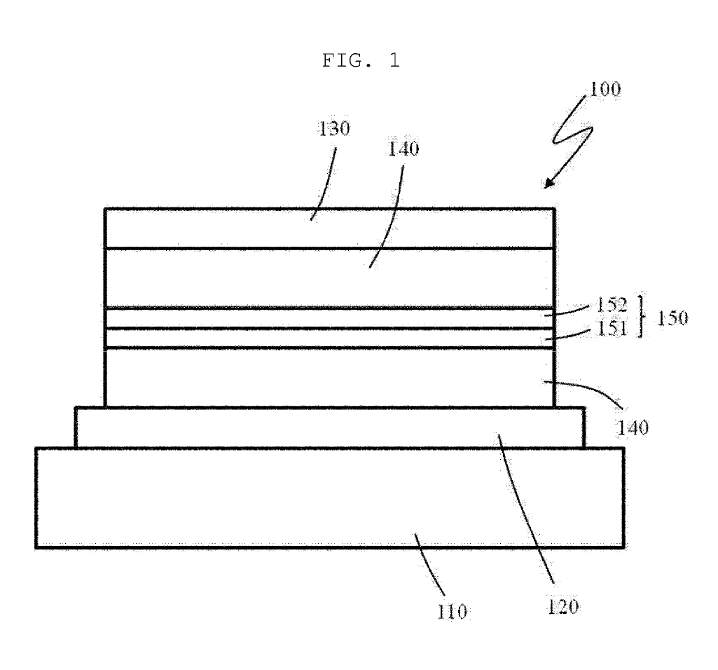

As illustrated in FIG. 1, a tandem OLED 100 according to an exemplary embodiment of the present invention includes a base substrate 110, a first electrode 120, a second electrode 130, organic light-emitting layers 140, and a charge generation layer (CGL) 150.

The base substrate 110 serves as a light guide through which light generated by the organic light-emitting layers 140 is emitted out. In this regard, the base substrate 110 is disposed in front of the organic light-emitting layers 140, i.e. in the direction in which light generated by the organic light-emitting layers 140 is emitted out. In addition, the base substrate 110 serves to protect a device layer including the first electrode 120, the second electrode 130, the organic light-emitting layers 140, and the CGL 150 from the external environment. In this regard, i.e. in order to encapsulate the device layer, the outer circumferential surface of the base substrate 110 is bonded to the outer circumferential surface of a rear substrate (not shown) disposed above the second electrode 130 to face the base substrate 110 by means of a sealing material, such as an epoxy, formed thereon. The inner space defined by the base substrate 110, the rear substrate (not shown) facing the base substrate 110, and the sealing material may be filled with inert gas or may be formed in a vacuum.

The base substrate 110 may be a transparent substrate that has superior light transmittance and mechanical properties. For example, the base substrate 110 may be formed of a polymeric material, such as a thermally or ultraviolet (UV) curable organic film. Alternatively, the base substrate 110 may be formed of chemically strengthened glass, such as soda-lime glass (SiO₂—CaO—Na₂O) or aluminosilicate glass (SiO₂—Al₂O₃—Na₂O). When the tandem white OLED 100 according to the embodiment of the present invention is applied to a lighting system, the base substrate 110 may be formed of soda-lime glass. The base substrate 110 may also be a substrate formed of a metal oxide or a metal nitride. According to the embodiment of the present invention, the base substrate 110 may be a thin glass substrate having a thickness of 1.5 mm or less. The thin glass substrate may be fabricated using a fusion process or a floating process. The rear substrate (not shown) cooperating with the base substrate 110 to form an encapsulation portion may be formed of the same material as or a different material from the base substrate 110.

The first electrode 120 is formed on the base substrate 110. The first electrode 120 is a transparent electrode acting as an anode of the tandem white OLED 100. The first electrode 120 may include a material selected from among materials having a greater work function to facilitate hole injection into the organic light-emitting layers 140, the selected material being able to enhance the transmission of light generated by the organic light-emitting layers 140. For example, the first electrode 120 may include indium tin oxide (ITO).

The second electrode 130 is disposed to face the first electrode 120, such that the organic light-emitting layers 140 and the CGL 150 are situated between the second electrode 130 and the first electrode 120. The second electrode 130 is a metal electrode acting as a cathode of the tandem white OLED 100. The second electrode 130 may include a material selected from among materials reflecting light generated by the organic light-emitting layers 140 forwardly, i.e. in the direction of the base substrate 110, the selected material having a smaller work function to improve electron injection. For example, the second electrode 130 may be a metal thin film formed of Al, Al:Li or Mg:Ag.

In addition, the second electrode 130 may form microcavities together with the first electrode 120 in order to improve the luminous efficiency of the tandem white OLED 100. When the second electrode 130 and the first electrode 120 form the microcavities, light generated by the organic light-emitting layers 140 is subjected to constructive interference and resonance within the microcavities, thereby improving luminous efficiency in the direction of the base substrate 110.

Two or more organic light-emitting layers 140 are formed between the first electrode 120 and the second electrode 130 in order to form the tandem white OLED 100. That is, the two or more organic light-emitting layers 140 alternate with one or more CGLs 150. Although not shown in the drawing, each of the organic light-emitting layers 140 may include, for example, a hole layer including a hole injection layer and a hole transport layer, an emission layer, and an electron layer including an electron transport layer and an electron injection layer. According to this structure, in the case in which one organic light-emitting layer 140 of the organic light-emitting layers 140 is situated between the first electrode 120 and the CGL 150, in response to a forward voltage being applied to the first electrode 120 and the second electrode 130, electrons migrate from the CGL 150 to the emission layer through the electron injection layer and the electron transport layer, and holes migrate from the first electrode 120 to the emission layer through the hole injection layer and the hole transport layer. In addition, in the case in which the organic light-emitting layer 140 is situated between the second electrode 130 and the CGL 150, electrons migrate from the second electrode 130 to the emission layer, and holes migrate from the CGL 150 to the emission layer. In the case in which the CGLs 150 are disposed above and below the organic light-emitting layer 140, electrons migrate from the upper CGL 150 to the emission layer, and holes migrate from the lower CGL to the emission layer. Electrons and holes injected into the emission layer as above recombine with each other to generate excitons. When such excitons transmit from an excited state to a ground state, light is emitted. The brightness of emission light is proportional to the amount of current flowing between the first electrode 120 acting as an anode and the second electrode 130 acting as a cathode.

According to an embodiment of the present invention, the emission layer of one organic light-emitting layer 140 of the organic light-emitting layers 140 may be formed of a high-molecular weight material for emitting light in a blue wavelength band, and the emission layer of the other organic light-emitting layer 140 of the organic light-emitting layers 140 may be formed of a low-molecular weight material for emitting light in an orange-red wavelength band. Then, white light is produced through color mixing of blue light and orange-red light generated by these emission layers. However, this is merely an example, and white light may be produced by forming a plurality of organic light-emitting layers 140 based on a variety of structures, shapes, and materials. One or more emission layers formed of a material for emitting a different color of light may be further provided as long as white light can be produced through color mixing with blue light.

The CGL 150 is formed between the adjacent organic light-emitting layers 140. The CGL 150 acts as an interconnecting layer since the CGL 150 serves to adjust the charge balance between the adjacent organic light-emitting layers 140. The CGL 150 may be formed using, for example, vacuum deposition, sputtering, sol-gel coating, and the like.

According to an embodiment of the invention, the CGL 150 may have a laminated structure of a first metal layer 151 and a second metal layer 152 having different work functions. Here, the first metal layer 151 abutting the electron injection layer or the electron transport layer of the electron layer of the organic light-emitting layer 140 positioned below the first metal layer 151 on the drawing acts as an n-type charge generation layer to facilitate the injection of electrons into the underlying organic light-emitting layer 140. It is preferable that the first metal layer 151 include a metal, the work function of which is lower than that of the second metal layer 142. According to an embodiment of the invention, the first metal layer 151 may include one element or a combination of two or more elements selected from among Li, Cs, Na, Ba, Ca, Mg, and Al. In addition, the second metal layer 152 abutting the hole injection layer or the hole transport layer of the hole layer of the organic light-emitting layer 140 positioned above the second metal layer 152 on the drawing acts as a p-type charge generation layer to facilitate the injection of holes into the overlying organic light-emitting layer 140. It is preferable that the second metal layer 152 includes a metal, the work function of which is greater than that of the first metal layer 151. According to an embodiment of the invention, the second metal layer 152 may include one element or a combination of two or more elements selected from among Au, Ag, Cu, Sn, Ti, and Al. The first metal layer 151 and the second metal layer 152 have different compositions since they include metals having different work functions.

The CGL 150 according to the embodiment of the present invention may have a very low thickness ranging, for example, from 0.1 nm to 50 nm. In this case, the characteristics of the first metal layer 151 and the second metal layer 152 serving to adjust the charge balance between the adjacent organic light-emitting layers 140 may be lost. In order to prevent this, the CGL 150 according to another embodiment of the present invention may further include an insulating layer (not shown) situated between the first metal layer 151 and the second metal layer 152. The insulating layer (not shown) may include a polymer insulating layer or may include one selected from among SiOₓ, SiNₓ, WO_{K}, MoOₓ, and Al₂O₃. In addition, the CGL 150 according to a further embodiment of the present invention may further include a semiconductor layer (not shown) formed between the first metal layer 151 and the second metal layer 152 in order to increase the charge mobility of the insulating layer (not shown). The semiconductor layer (not shown) may include one selected from among conjugated polymers, conjugated molecules, metal oxides, and silicon.

As set forth above, in the tandem white OLED 100 according to the embodiments of the present invention, the CGL 150 has a two-layer structure of the first metal layer 151 and the second metal layer 152 having different work functions, a three-layer structure in which the insulating layer (not shown) is situated between the first metal layer 151 and the second metal layer 152, or a three-layer structure in which the semiconductor layer (not shown) is situated between the first metal layer 151 and the second metal layer 152. It is thereby possible to improve the conductivity of the CGL 150, whereby the tandem white OLED 100 can realize superior electrical properties.

The foregoing descriptions of specific exemplary embodiments of the present invention have been presented with respect to the drawings. They are not intended to be exhaustive or to limit the present invention to the precise forms disclosed herein, and many modifications and variations are obviously possible for a person having ordinary skill in the art in light of the above teachings.

It is intended therefore that the scope of the present invention should not be limited to the foregoing embodiments, but shall be defined by the Claims appended hereto and their equivalents.

1. A tandem white organic light-emitting device comprising:
a base substrate;
a first electrode disposed on the base substrate;
a second electrode facing the first electrode;
two or more organic light-emitting layers disposed between the first electrode and the second electrode; and
one or more charge generation layers respectively disposed between adjacent organic light-emitting layers among the two or more organic light-emitting layers,
wherein each of the charge generation layers has a laminated structure comprising a first metal layer and a second metal layer having different work functions.

2. The tandem white organic light-emitting device according to claim 1, wherein the work function of the first metal layer is lower than the work function of the second metal layer.

3. The tandem white organic light-emitting device according to claim 2, wherein the first metal layer abuts an electron layer of one organic light-emitting layer among the two or more organic light-emitting layers, and the second metal layer abuts a hole layer of an adjacent organic light-emitting layer among the two or more organic light-emitting layers.

4. The tandem white organic light-emitting device according to claim 3, wherein the first metal layer comprises one element or a combination of two or more elements selected from the group consisting of Li, Cs, Na, Ba, Ca, Mg, and Al.

5. The tandem white organic light-emitting device according to claim 4, wherein the second metal layer comprises one element or a combination of two or more elements selected from the group consisting of Au, Ag, Cu, Sn, Ti, and Al.

6. The tandem white organic light-emitting device according to claim 1, wherein each of the charge generation layers further comprises an insulating layer situated between the first metal layer and the second metal layer.

7. The tandem white organic light-emitting device according to claim 6, wherein the insulating layer comprises a polymer insulating layer or comprises one selected from the group consisting of SiOₓ, SiNₓ, WO_{K}, MoOₓ, and Al₂O₃.

8. The tandem white organic light-emitting device according to claim 1, wherein each of the charge generation layers further comprises a semiconductor layer situated between the first metal layer and the second metal layer.

9. The tandem white organic light-emitting device according to claim 8, wherein the semiconductor layer comprises one selected from the group consisting of conjugated polymers, conjugated molecules, metal oxides, and silicon.

10. The tandem white organic light-emitting device according to claim 1, wherein a thickness of each of the charge generation layers ranges from 0.1 nm to 50 nm.
